(19) United States
(12) Patent Application Publication
(10) Pub. No.: US 2007/0202655 A1
(43) Pub. Date: Aug. 30, 2007

(54) Method of providing a via opening in a dielectric film of a thin film capacitor

(75) Inventor: Yongki Min, Phoenix, AZ (US)

Correspondence Address: INTEL CORPORATION;c/o INTELLEVATE, LLC, P.O. BOX 52050, MINNEAPOLIS, MN, 55402, US

(73) Assignee: Intel Corporation

(21) Appl. No.: 11/297,854

(22) Filed: Dec. 8, 2005

(51) Int. Cl. H01L 21/20

(52) U.S. Cl. 438/381

(57) ABSTRACT

An embedded passive structure, its method of formation, and its integration onto a substrate during fabrication are disclosed. A method comprises providing a thin film capacitor laminate that comprises: a high-k ceramic dielectric film; a conductive film disposed on one side of the high-k ceramic dielectric film; and a first electrode layer including first conductive portions disposed on another side of the high-k ceramic dielectric film. The method further comprises providing through via openings in the high-k ceramic dielectric film using powder blasting; and patterning the conductive film to yield a intermediate second electrode layer including intermediate second conductive portions disposed on the one side of the high-k ceramic dielectric film.

### FIELD OF THE INVENTION

Embodiments of the present invention relate generally to methods of providing via openings adapted to be used for vias in a microelectronic package.

### BACKGROUND OF THE INVENTION

The demand for increased mobility in consumer electronics is pressuring manufacturers to scale electronic technologies (e.g., semiconductor devices) to ever smaller dimensions. At the same time, the demand for increased functionality, speed, noise elimination, etc., is forcing manufactures to increase the number of passive components (e.g., capacitors and resistors) used by consumer electronic devices. Passive component integration has traditionally been accomplished by mounting them onto package and/or printed circuit board (PCB) substrate surfaces. Restricting the location of the passive components to the substrate's surface however can limit the passive components' operational capabilities (due to their inherent distance from the semiconductor device) and the substrate's scalability.

One way manufacturers are attempting to address this is by embedding the passive components in the substrate, a technique referred to as embedded passive technology. This frees up surface real estate and facilitates substrate miniaturization. Speed and signal integrity also improves because embedded components provide a more direct path through which the IC signals propagate.

One particular area of interest with respect to embedded passive technology has been the incorporation of thin film capacitors (TFCs) into organic packaging (e.g., bismaleimide triazine resin, etc.) substrates. It is desirable to provide decoupling capacitance in a close proximity to an integrated circuit chip or die. The need for such capacitance increases as the switching speed and current requirements of chips or dies becomes higher. Among the various materials being considered for use as capacitor dielectrics are high-k ceramic materials. However, high-k ceramic materials can require processing at high temperatures (e.g., furnace annealing at 600-800 degrees Celsius) in order to achieve their high dielectric constant properties. At these temperatures, organic packaging substrates can melt.

One technique for addressing this involves mounting a pre-fabricated TFC laminate that has already been annealed onto the organic substrate. Such TFC laminates may include a high-k ceramic material superimposed between two conductive films which will serve, respectively, as the top and bottom electrode structures of the TFC laminate. Typically, the bottom of the conductive films has already been patterned according to the pattern of the bottom electrode structure. Such a laminate is, according to the prior art, mounted onto a microelectronic substrate which may include polymer build-up layers and conductive build-up layers, the conductive build-up layers connecting with additional underlying conductive structures. After mounting of the TFC laminate, the top conductive film may be patterned to form the upper electrode. Then, via openings are formed through the high-k ceramic material, the polymer build-up layers, and, in some cases, portions of the lower electrode structures. The via openings are typically provided using a UV YAG laser to drill the via holes. It has been found that CO2 laser processes or even wet etching processes previously sought to be used do not reliably penetrate through the high-k ceramic material of the TFC laminate. However, use of the UV laser typically leads to thermal damage of the via edge regions (the damaged regions being called the “heat affected zone”) causing electrical shorting issues in the TFC, thereby impacting the functionality of the final package that includes the TFC.

### BRIEF DESCRIPTION OF THE DRAWINGS

FIGS. 1-5b and 7-8 illustrate sectional views showing formation of an embedded passive components in a substrate according to one embodiment; and

FIGS. 6a-6b show an arrangement for effecting powder blasting to create via openings in a dielectric film of an embedded passive components according to an embodiment.

For simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, an embedded passive structure and its method of formation are disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention.

The terms on, above, below, and adjacent as used herein refer to the position of one layer or element relative to other layers or elements. As such, a first element disposed on, above, or below a second element may be directly in contact with the second element or it may include one or more intervening elements. In addition, a first element disposed next to or adjacent a second element may be directly in contact with the second element or it may include one or more intervening elements.

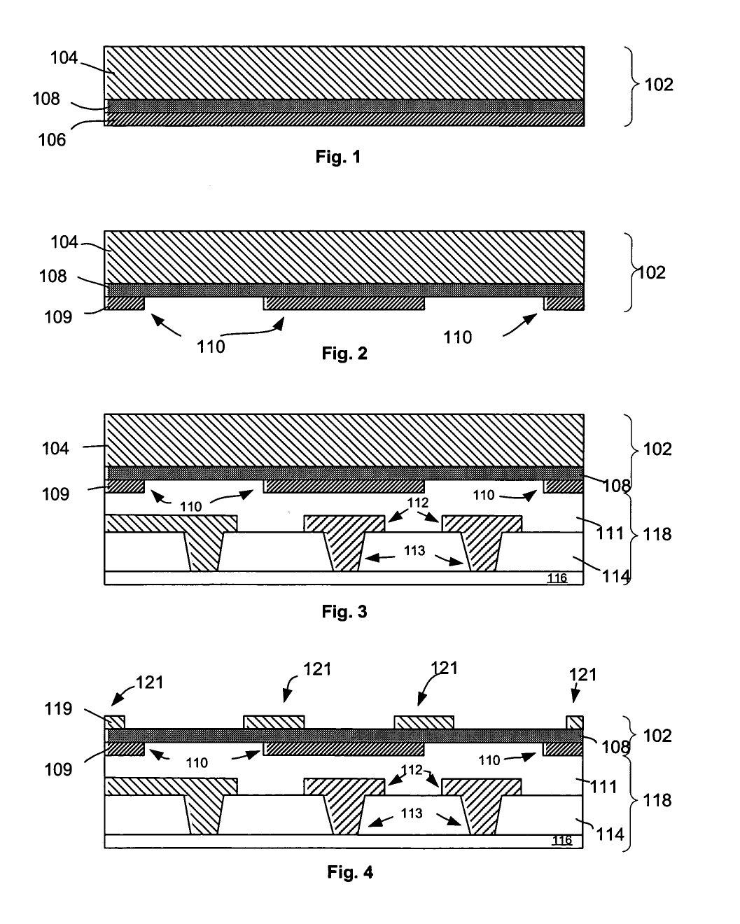

In one embodiment, a thin film laminate for use in the fabrication of embedded passives and its method of formation are disclosed. In one embodiment, the formation of embedded passive structures using a thin film laminate mounted on a substrate is disclosed. Aspects of these and other embodiments will be discussed herein with respect to FIGS. 1-8, below. The figures, however, should not be taken to be limiting, as they are intended for the purpose of explanation and understanding.

FIGS. 1-5b, 7 and 8 show stages illustrating a method of formation of a microelectronic package including a thin film laminate, such as for example, thin film capacitors (TFCs), and a packaging substrate, a PCB substrate, or the like, into which the TFC is embedded. More specifically, FIGS. 1-5b, 7 and 8 illustrate a formation of a microelectronic package in which through via openings are formed in the high-k ceramic material of the TFC using powder blasting, such as, for example, sand blasting. The term “microelectronic substrate” or “substrate” as used herein, is intended to encompass any type of packaging substrate, PCB substrate, etc., which can be used to accommodate embedded passive components.

In FIG. 1, a cross-sectional view of a TFC laminate 102 is shown, which includes a high-k ceramic film 108 between respective top and bottom conductive films 104 and 106. Typically, the conductive films 104 and 106 may include metal materials, such as copper, nickel, platinum or the like. In one embodiment, the top conductive film 104 comprises a copper film having a thickness of about 30 microns, the bottom conductive film 106 comprises a nickel film having a thickness between about 20 to about 30 microns, and the high-k ceramic material 108 comprises a sputtered on film made of barium strontium titanate (BST) and having a thickness of about 0.4 to about 0.6 micron. However, any number of materials can be used to form the high-k ceramic film, such as, for example, barium titanate (BaTiO3), strontium titanate (SrTiO3), barium strontium titanate (BaSrTiO3), or the like. Provision of the high-k ceramic film 108 may be effected according to any one of well known techniques, such as, for example, PVD (including evaporation, sputtering, etc.), CVD, a sol-gel process (for example, a spin-on process), laser ablation, green sheet technology or the like. Provision of the high-k ceramic film may be effected, by way of example, onto the either one of the top or bottom conductive films, which, in that case, would serve as a base layer for the high-k ceramic film, as would be within the knowledge of one skilled in the art. The subsequent bottom or top conductive film would then be provided onto the high-k ceramic film using, by way of example, a PVD process, combination PVD and electroplating or electroless plating processes, or the like.

Referring next to FIG. 2, a cross-sectional view is shown of the structure of FIG. 1 after patterning of the bottom conductive film 106 to yield a bottom electrode structure or layer 109 including the remaining bottom conductive film portions 110 to yield a partially patterned TFC laminate 102. A patterning of the bottom conductive film 106 may be effected using conventional photolithography and etching, as would be within the knowledge of one skilled in the art.

Turning now to FIG. 3, a cross-sectional view is shown of the structure of FIG. 2 after its having been mounted onto a microelectronic substrate 118 that includes polymer build-up layers 111, 114, and conductive build-up layers including interconnects 112 and vias 113 as shown. The interconnects 112 and vias 113 connect with underlying conductive structures (not shown). The partially patterned TFC laminate 102 may be mounted such that the bottom electrode structure 109 contacts the substrate as shown. The polymer build-up layers 111 and 114 may be formed, for example, using a dielectric material, such as an Ajinomoto Build-up Film (ABF). The interconnects and vias may be formed, for example, using copper. The use and formation of build-up layers is known to one of ordinary skill. Underlying the vias 113 and build-up dielectric film 114 is layer 116, which may include an organic core material as know to one of ordinary skill, and/or additional dielectric and conductive build-up layers. To improve adhesion between the partially patterned TFC laminate 102 and the substrate 118, the partially patterned TFC laminate 102 and substrate 118 can be joined after roughening the conductive portions 110 and prior to curing the build-up layer 111. The conductive regions 110 can be roughened using chemical etching, sputter etching, and/or like processes. One of ordinary skill appreciates that the fragile nature of the partially patterned TFC laminate 102 and its relative alignment to the underlying substrate 118 can be important considerations with respect to mounting the partially patterned TFC 102 onto the substrate 118.

Next, referring to FIG. 4, the top conductive film 104 is thinned and then patterned to form an intermediate top electrode layer 119 including top intermediate electrode portions 121. Layer 119 and electrode portions 121 are referred to herein as “intermediate” since they do not constitute the top electrode layer and the top electrodes proper, but rather represent intermediate structures in a process of forming the top electrode layer and top electrodes, as will become apparent hereinafter. Thinning may be accomplished using, for instance, a wet etch process, a dry etch process, a polishing process, combinations thereof, or the like. In an embodiment where the top conductive film 104 is made of nickel, thinning may be accomplished by way of etching with a wet etchant, such as ferric chloride (FeCl₃) prior to patterning. In one embodiment, the top conductive film 104 may be thinned to between about 10 to about 20 microns to yield the intermediate top electrode layer 119. Thinning facilitates a patterning of intermediate top electrode layer 119 by reducing the amount of conductive material that must be removed. Thinning at this point in the processes may be advantageous because, during earlier stages of the partially patterned TFC laminate 102 fabrication, the thicker top conductive film 104 is stronger and less susceptible to physical/chemical damage during formation of the capacitor dielectric and bottom electrode structures. After thinning, the top conductive film 104 may be patterned with resist and then etched to define the intermediate top electrode layer 119. Etching may be accomplished using wet or dry etch processes. In one embodiment, the thinned top conductive film 104 may be etched using a ferric chloride solution to yield the intermediate top electrode layer 119.

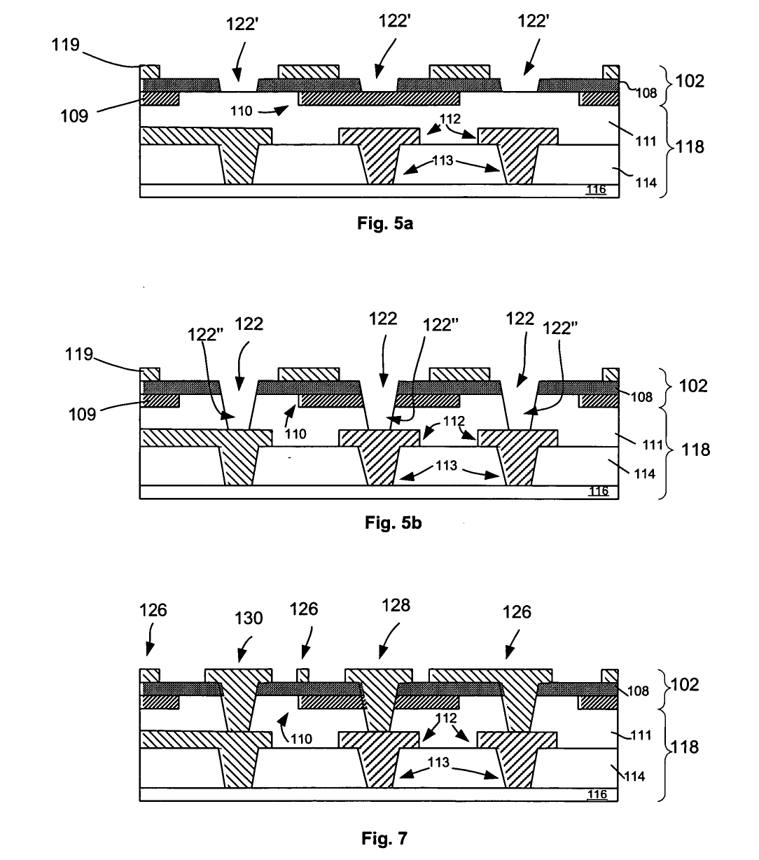

Next, shown in FIGS. 5a and 5b, the substrate is patterned to define package via openings 122 through the high-k ceramic film 108, through the polymer build-up layer 111, and in some cases, through portions of the bottom electrode portions 110. The package via openings may be formed to expose underlying portions of the conductive build-up layers of the substrate including interconnects 112 as shown. According to embodiments, a formation of the package via openings 122 includes, at first, as shown in FIG. 5a, a formation of through via openings 122′ of the package via openings through the high-k ceramic material using powder blasting, such as, for example, sand blasting, and, thereafter, as shown in FIG. 5b, a subsequent formation of substrate via openings 122″ of the package via openings 122 through the polymer build-up layer and possibly through portions of the bottom electrode portions using conventional techniques such as, for example, a laser drilling process using a UV YAG laser or a CO2 layer, or a conventional photolithography/etch patterning process, or the like. It is noted that the via openings 122′ are referred to herein as “through via openings” as they extend from one surface of the high-k ceramic film to an opposing surface thereof, while via openings 122″ are referred to herein as “substrate via openings” as they extend through portions of the substrate, while via openings 122, which are a composite of the through via openings 122′ and of the substrate via openings 122″, are referred to herein as “package via openings.” Substrate via openings 122″ are provided to be in registration with through via openings 122′, as clearly seen in the figures.

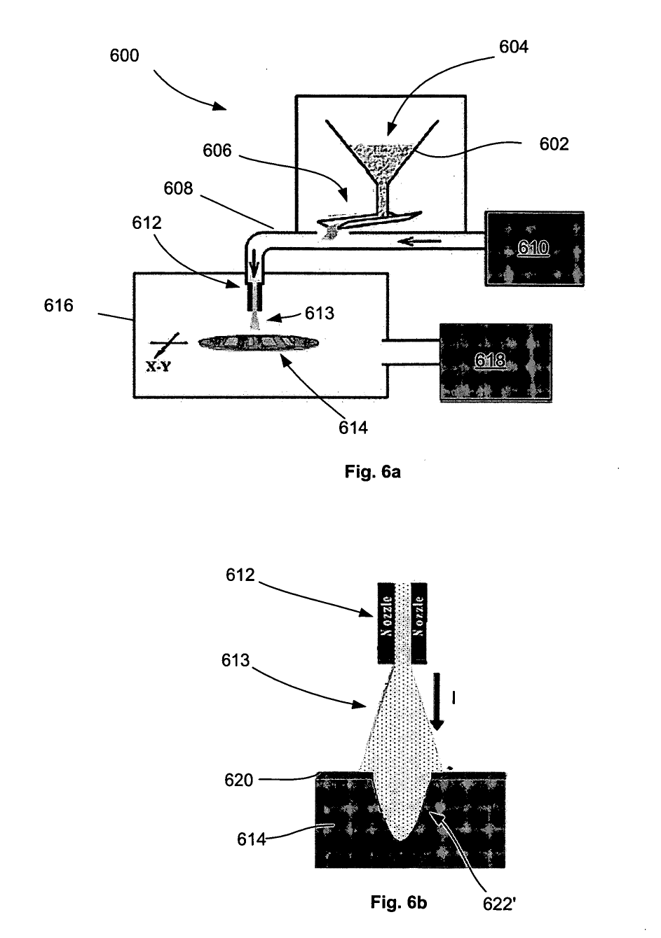

Referring next to FIGS. 6a and 6b, an arrangement is shown to effect a powder blasting of the high-k ceramic film 108 of the TFC laminate in order to form through via openings 122′ in the high-k ceramic material of film 108. As shown in FIG. 6a, arrangement 600 includes a reservoir 602 containing a powder medium 604 adapted to effect powder blasting. An example of such a powder medium includes aluminum oxide particles having a particle size of between about 3 and about 30 microns, and preferably a particle size of about 10 microns in order to obtain a high resolution, such as a resolution of about 30 microns of via openings created as a result of use thereof in powder blasting. Other examples of a powder medium include silicon carbide, boron nitride, boron carbide and the like. The hopper dispenses into a feeder 606, which may, in one embodiment, be a vibrating feeder. The powder medium 604 is dispensed into a powder feed tube 608 into which dry compressed air is pumped by way of an air feed pump 610, which may pump the air at a pressure less than 6 bar into the tube 608. Tube 608 in turn feeds the powder medium and compressed air into a nozzle, such as, for example, a Venturi nozzle 612. Nozzle 612 then directs a jet 613 of the powder medium, at a pressure of, for example 100 psi, toward target 614 which may, according to embodiments, include a microelectronic substrate such as a high-k ceramic film. The arrangement 600 may be configured in a well known manner such that the nozzle 612 and/or the target is/are translatable in the X and/or Y direction(s) in order to ensure a substantially evenly etched surface of the target. According to one embodiment, the arrangement 600 may further be configured such that the nozzle may be placed at an angle with respect to the target, and further such that the target is rotatable with respect to the nozzle, in order to allow improved control of the obtained via openings shape, as would be recognized by one skilled in the art. Etching by way of powder blasting may take place, as shown, in a blasting chamber 616 that is connected to a cyclone ventilation device 618 adapted to separated the powder particles from the air flow, as would be recognized by one skilled in the art.

Referring next to FIG. 6b, a more detailed view of the nozzle 612 and of the target 614 is shown. Here, the target 614 is clearly shown as being covered with a mask 620 patterned according to a predetermined pattern, such as, for example, according to a predetermined pattern of vias to be provided through a high-k ceramic film. The mask may comprise a metal or a polymer layer, such as, for example, a polyimide, electroplated copper, and the like, and may have a thickness between about 10 microns to about 20 microns. The mask is made of a material adapted to resist erosion by the jet of powder medium. Preferably, the mask comprises an electroplated copper mask in order to be able to combine a low erosion rate of metals with the high resolution of lithographic processes. Jet 613 of powder medium may be accelerated by nozzle 612 toward the target in an impingement direction 1, at a velocity of, for example, about 80 to about 300 m/s. The mixture of powder medium and compressed air may enter the nozzle at a pressure of about 1 to about 5 Bar. A blasting of the target by the shown arrangement may result in the formation of a via opening in the target 614, beginnings of which are shown as partially formed via opening 622′ in FIG. 6b.

Although an exemplary embodiment of a powder blasting arrangement is shown with respect to FIGS. 6a and 6b, embodiments comprise within their scope any powder blasting arrangement adapted to create via openings within the high-k ceramic film of a TFC laminate, as would be within the knowledge of a person skilled in the art. In addition, although exemplary process parameters have been set forth above for powder blasting a high-k ceramic film, it is understood that other parameters would be within the purview of embodiments.

Referring next to FIG. 7, a conductive fill material is shown as having been deposited in via openings 122 and over the surface of the TFC where it may then be thinned and patterned according to conventional techniques in order to form top conductive structures including top electrode portions 126, biasing interconnects 128 for the bottom electrodes, I/O interconnects 130, build-up interconnect structures, and/or the like. Suitable materials for forming a conductive fill material inside via openings 122 and over the surface of the TFC may include copper, aluminum, or the like. According to one embodiment, the conductive fill material is deposited by first globally depositing a seed layer of copper, such as one having a thickness less than about one micron, using an electroless plating or PVD process, followed by deposition of a full thickness copper material using an electroplating process. After provision of the conductive fill material, as noted above, it may be thinned and patterned to define the completely formed upper electrode and associated conductive structures as described. Thinning may be accomplished, for instance, using wet chemical etch process, a dry etch process, a chemical mechanical polishing process, and/or the like. Patterning may be accomplished using a conventional lithographic and etch patterning process, a lift-off process, or the like. One of ordinary skill will appreciate that other integration schemes for forming the top conductive structures could also include, for example, a complete removal of the top conductive film 104 (instead of thinning and patterning to form partially defined top electrode layer structures) followed by a seed layer deposition, a full thickness conductive layer deposition, and pattering to define the conductive structures 126, 128 and 130. Embodiments of the present invention are not necessarily limited to only the formation of structures such as 126, 128 and 130. Any number of other interconnect features associated with the formation of build-up layer technology can be accommodated using one or more of the integration schemes disclosed herein.

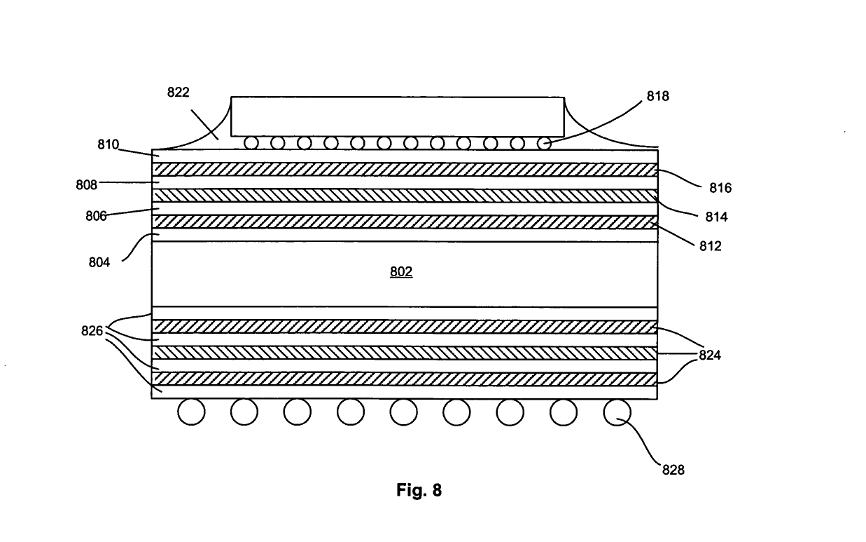

Subsequent processing is considered conventional to one of ordinary skill. So, for example, referring to FIG. 8, which shows the relative positional relationships of conductive build-up layers 812, 814, 816, 824, polymer build-up layers 804, 806, 808, 810, 826, an organic core material 802, a semiconductor die 820, underfill material/fillets 822, die-to-package interconnects 818, and package-to-PCB interconnects 828, if TFC structures similar to one or more of those disclosed in FIGS. 1-7 were incorporated into, for instance, the conductive build-up layer 814 (TFC structures not shown), then additional conductive build-up layer 816 and polymer build-up layers 808 and 810 could additionally be formed overlying them using conventional methods. Following the formation of the desired number of build-up layers, the semiconductor die can be attached to the package substrate using conventional die attach reflow methods, bump interconnects 828 could be attached to the package substrate using conventional methods (e.g. ball grid array (BGA) reflow methods), and then the integrated package that includes the passive TFCs could be mounted to a PCB, a mother board, or the like, for use by the electronic device.

It is noted that, although the embodiments described above relate to the formation of through via openings in a thin film capacitor after its having been mounted onto an organic substrate, embodiments are not so limited. Thus, embodiments comprise within their scope the formation of through vias in a high-k ceramic film of a thin film capacitor using powder blasting prior to its mounting onto an organic substrate. In addition, although the embodiments described above relate to a patterning of the top conductive film to yield intermediate conductive portions after a mounting of the thin film capacitor onto the organic substrate, embodiments also comprise within their scope the patterning of the top conductive film at any time during the embedding process, such as, for example before a mounting of the thin film capacitor onto the organic substrate.

Advantageously, providing through via openings in high-k ceramic films of embedded thin film capacitors provides a low-cost, low-risk and high throughput embedding process for the thin film capacitors into an organic packaging substrate. Embodiments aim toward a via patterning process of thin film capacitors by powder blasting as opposed to the current UV laser via drilling process. Thus, according to embodiments, heat affected zones in high-k ceramic films of thin film capacitors are advantageously avoided, in this way obviating shorting issues and improving device functionality. Additionally, a powder blasting method for providing through via openings in high-k ceramic films of thin film capacitors advantageously provides a high throughput process as compared with prior art processes, among other things because powder can easily be blasting over large surfaces.

The various embodiments described above have been presented by way of example and not by way of limitation. Thus, for example, while embodiments disclosed herein teach the formation of embedded capacitors in build-up layer of a packaging substrate, other passive structures, such as for example inductors, resistors, etc., can similarly be formed and/or accommodated using one or more of the embodiments disclosed herein. Also, these passive components can be formed in any number of substrate types that can accommodate the incorporation TFC laminates.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A method of forming an embedded thin film capacitor comprising:
providing a thin film capacitor laminate comprising:
a high-k ceramic dielectric film;
a conductive film disposed on one side of the high-k ceramic dielectric film; and
a first electrode layer including first conductive portions disposed on another side of the high-k ceramic dielectric film;
providing through via openings in the high-k ceramic dielectric film using powder blasting;
patterning the conductive film to yield a intermediate second electrode layer including intermediate second conductive portions disposed on the one side of the high-k ceramic dielectric film.

2. The method of claim 1, wherein providing through via openings occurs after patterning the conductive film.

3. The method of claim 1, wherein
the first electrode layer is a bottom electrode layer;
the first conductive portions are bottom conductive portions;
the intermediate second electrode layer is an intermediate top electrode layer; and
the intermediate second conductive portions are intermediate top conductive portions.

4. The method of claim 3, further comprising:
providing a substrate including a dielectric build-up layer and a conductive build-up layer;
mounting the thin film capacitor laminate onto the dielectric build-up layer of the substrate such that the bottom conductive portions are disposed between the dielectric build-up layer and the high-k ceramic film.

5. The method of claim 4, further comprising:
providing substrate via openings in registration with the through via openings in the high-k ceramic dielectric film to form package via openings, the substrate via openings extending through the dielectric build-up layer of the substrate to the conductive build-up layer; and
filling the package via openings with conductive fill material to provide package vias.

6. The method of claim 5, wherein providing substrate via openings comprises using a UV laser, a CO2 laser and lithography.

7. The method of claim 1, wherein patterning the conductive film comprises using lithography and one of a wet etch and a dry etch.

8. The method of claim 7, wherein patterning the conductive film comprises thinning the conductive film before using lithography using at least one of a wet etch, a dry etch and a polishing process.

9. The method of claim 5, wherein patterning the conductive film occurs after mounting and comprises:
patterning the conductive film to obtain an intermediate top electrode layer; and
after providing through via openings, patterning the intermediate top electrode layer and portions of the conductive fill material disposed on the high-k ceramic film layer to obtain the top electrode layer.

10. The method of claim 1, wherein the high-k ceramic dielectric film comprises a material selected from a group consisting of strontium titinate, barium strontium titinate and/or barium titinate.

11. The method of claim 1, wherein each of the conductive film and the first electrode layer comprises at least one of copper, nickel and platinum.

12. The method of claim 1, wherein using powder blasting comprises using a powder medium including at least one of alumina oxide particles, silicon carbide particles, boron nitride particles and boron carbide particles.

13. The method of claim 1, wherein using powder blasting comprises using a powder medium having an average particle size of between about 3 microns and about 30 microns.

14. The method of claim 1, wherein using powder blasting comprises directing a jet of powder medium toward the high-k ceramic film at a velocity of about 80 to about 300 m/s.

15. The method of claim 1, wherein using powder blasting comprises powder blasting the high-k ceramic film through a mask disposed thereon, the mask having a predetermined pattern according to a pattern of the through via openings.

16. The method of claim 15, wherein the mask comprises one of a metal layer and a polymer layer.

17. The method of claim 15, wherein the mask comprises a layer of electroplated copper.

18. The method of claim 1, wherein using powder blasting comprises using an arrangement including a nozzle adapted to direct a jet of powder medium toward the high-k ceramic film, the arrangement being configured such that at least one of the nozzle and the high-k ceramic film are translatable relative to one another during powder blasting.

19. The method of claim 1, wherein using powder blasting comprises using an arrangement including a nozzle adapted to direct a jet of powder medium toward the high-k ceramic film at adjustable angles during powder blasting.

20. The method of claim 19, wherein the arrangement is further configured such that the high-k ceramic film is rotatable with respect to the nozzle during powder blasting.

21. The method of claim 9, further comprising patterning portions of the conductive fill material disposed above the high-k ceramic film to form interconnects on the high-k ceramic film.

22. The method of claim 5, wherein filling the package via openings comprises:
using one of an electroless plating process and a PVD process to deposit a seed conductive layer; and
using an electroplating process to deposit a remaining portion of the conductive fill material to fill the package via openings.

23. A method of forming an embedded thin film capacitor comprising mounting the capacitor to an organic packaging substrate, wherein the organic packaging substrate includes embedded thin film capacitors having high-k ceramic films in which through via openings have been provided using powder blasting.

24. The method of claim 23, wherein the organic packaging substrate is characterized as a ball grid array packaging substrate.
